(19) United States
(12) Patent Application Publication
(10) Pub. No.: US 2022/0015240 A1
(43) Pub. Date: Jan. 13, 2022

(54) METHOD AND DEVICE FOR CREATING AT LEAST A PART OF ELECTRONIC CIRCUIT, AND ELECTRONIC CIRCUIT

(71) Applicant: MACSA ID, S.A., SANT FRUITOS DE BAGES (BARCELONA) (ES)

(72) Inventor: Venkatesh Seshaiya Doraiswamy Chandrasekar, ROTTERDAM (NL)

(21) Appl. No.: 17/289,958

(22) PCT Filed: Nov. 29, 2019
(86) PCT No.: PCT/EP2019/083194

§ 371 Date: Apr. 29, 2021

(30) Foreign Application Priority Data
Nov. 30, 2018 (NL) 2022106

(51) Int. Cl. H05K 3/10; H05K 1/03

(52) U.S. Cl. CPC H05K 3/105; H05K 2203/107; H05K 1/0386

(57) ABSTRACT

Method of creating at least a part of an electronic circuit, comprising the steps of providing at least one carbonizable substrate, in particular a cellulose based substrate, and position-selectively irradiating at least one part of the substrate to a temperature exceeding the carbonization temperature of said substrate, such that the irradiated part of the substrate is carbonized to form at least one electrically conductive track and/or pad; and device comprising: at least one irradiation source, in particular a laser, such as a CO2 laser, being configured to position-selectively irradiate at least one part of a carbonizable substrate to a temperature exceeding the carbonization temperature of said substrate, such that the irradiated part of the substrate is carbonized to form at least one electrically conductive track and/or pad.

The invention relates to a method of creating at least a part of an electronic circuit. The invention also relates to a device for creating at least a part of an electronic circuit. The invention further relates to an electronic circuit, or at least a part thereof, created by using the method according to the invention.

Electronic circuits contain electronics (electric) components such as resistors, transistors, capacitors and the like which are connected to each other by conductive tracks through which electrons can flow. These electrically conductive tracks are made with conductive materials such as most metals. Highly conductive metals such as silver, copper is preferred for making conductive tracks but the drawback of such is that they are usually expensive, sometimes exploitative to mine and have certain limitations in the manner of applying them on the electronic circuits. Furthermore, there is growing market of conductive ink technology which offers users more flexibility in applying conductive tracks on packages for logistics or track and trace purposes such as in RFID antennas chips, for rapid prototyping of circuits, in photovoltaics, wearables etc. The disadvantage of the conductive inks is that these inks require the use an additional expensive consumable such as silver metal or nickel or suspended graphite in a polymer blend to make the inks conductive. Apart from the need to use an additional conductive consumable, the manner of application using a complicated and expensive printing device brings certain disadvantages as well. There is a general need to realise an electronic circuit, or at least a part thereof, having the benefits of conductive ink, though without having the disadvantage of needing consumable(s), preferably in a cost-effective manner.

It is an object of the invention to fulfill at least one of the aforementioned needs.

To this end, the invention provides a method according to the preamble, comprising the steps of: A) providing at least one carbonizable substrate, in particular a cellulose based substrate, B) position-selectively irradiating at least one part of the substrate to a temperature exceeding the carbonization temperature of said substrate, such that the irradiated part of the substrate is carbonized to form at least one electrically conductive track and/or pad. The method according to the invention is based by using a carbonizable substrate and by subsequently position-selectively carbonizing said substrate to form electrically conductive tracks and/or electrically conductive pads. Hence, there is no need any more to use additives (consumable), like conductive, metallized ink, and/or metals as such to create the tracks and pads. The track and pad creation which is achieved by using the method according to the invention can be considered as inkless printing, wherein the carbonized parts of the substrate contains carbon particles and/or carbon fibres (char) having electrically conductive properties.

The carbonization used during step B) of the method according to the invention is typically based upon pyrolysis, and hence is also referred to as pyrolytic carbonization. The advantages of pyrolytic carbonization is that carbon can be produced in a relatively simple and cost-efficient manner, without needing complicated facilities. Typically, at an early stage of pyrolysis (400° C.<T<600° C.), cyclization and aromatization proceed in the carbonizable substrate, typically formed by an organic precursor, with the release of various organic compounds like hydrocarbons, and inorganic matters such as CO, CO₂, H₂O, mainly because some of the C—C bonds are weaker than C—H bonds. Over 600° C., out-gassing is typically hydrogen (H₂) due to the polycondensation of aromatics. Up to 1500° C., though this temperature doesn't have to be necessarily reached, the residues which have “suffered” from carbonization may be called carbonaceous solids though they might still contain hydrogen. Above 1500, graphitization begins so the residues contain more than 99% of C which are thus called carbon materials. The occurrence of reactions, including cyclization, aromatization, polycondensation and graphitization, depends strongly on the substrate used as well as heating conditions. Sometimes these processes overlap with each other throughout pyrolysis and therefore, the whole process from precursor to the final carbon residues is often simply called “the carbonization”. In the method according to the invention at least cyclization and aromatization take place, but preferably also polycondensation, and more preferably also graphitization, will or may take place, in order to reduce the electrical resistance of the formed tracks and pads as much as possible.

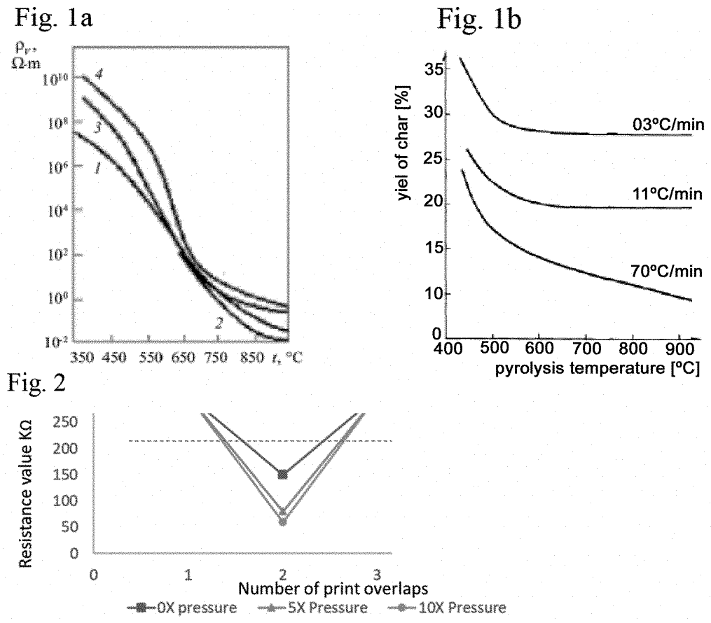

With reference to FIG. 1a, it is indicated that research teaches that there is a relationship between heat treatment temperatures (HTT) and electrical resistivity of different carbonizable substrates (1, 2, 3, 4), in particular biomass precursors. More in particular, an increase of HTT, within a temperature range of 350-900 degrees Celsius, declines observably the electrical resistivity, thus indicating a rise of electrical conductivity. Pyrolysis up to 750° C. allow to convert all types of biomass into conducting agents, which is also in agreement with the fact that the higher heat treatment temperature is, the purer carbon material is obtained. From this point of view, it is desired to apply a carbonization which is considerably higher than the minimum carbonization temperature of about 400 degrees Celsius. Here, it is for example preferred to use a temperature of 750-800 degrees Celsius in order to get relatively good conductivity results while using a relatively limited amount of irradiated energy.

Moreover, with reference to FIG. 1b, it is indicated research also shows that heating rate is important for the char yield and the char properties in cellulose pyrolysis. This research showed that a change of heating rate from 70 to 0.03 degrees Celsius per minute (° C./min) results a considerable increase in char yield from 11% to 28% at the end of pyrolysis at 900° C. This is most likely due to a prolongation of dehydration reaction at low temperature (<240° C.), which leads also to thermally more stable char with a low oxygen content. This higher carbon particle or carbon fibre content normally provides a higher blackness of the realized track and/or pad. With examination of char properties, it was concluded that low heating rates help likewise to yield highly porous but dense chars. This leads to the insight that is preferred to apply a restricted heating rate which is lower than or equal to 30 degrees Celsius per minute, preferably lower than or equal to 15 degrees Celsius per minute, in case only a single irradiation step would be performed. However, in case more irradiation steps are performed, for example by preheating and/or post-irradiation, the substrate, as also described in this patent specification, then (significantly) higher heating rates could be applied, which is interesting from an economic and commercial point of view.

It has also been found that the flame retardants could facility and stabilize the pyrolysis process of the carbonizable substrate. For example, the preferred presence of dihydrogen phosphate (GDP), ammonium phosphate (DAP), and diguanidine hydrogen phosphate (DHP) in and/or on the substrate leads to an increase of 33% on carbon yield. Moreover, water-soluble organosilicon, whether alone or mixed with other ammonium additives, also helps increasing carbon yield to an important extent and improving simultaneously mechanical resistivity of carbon particles and carbon fibres. It was also found that impregnation of the substrate with a diluted sulfuric acid solution before step B) is performed, or conducting the pyrolysis process of step B) in a hydrogen chloride (HCl) atmosphere helps increase the carbon yield to 38%. Hence, it is preferred that the substrate is treated with at least one of the aforementioned additives prior to performing step B) and/or to subject the substrate during step B) in an acidic environment. Instead of applying an acidic environment during step B), it will be clear that step B) may also be applied in air (atmospheric conditions) or in an inert atmosphere.

Carbonizable substrates refer to substrates, in particular sheets or layers, which can get carbonised at elevated temperature, typically temperatures of 400 degrees Celsius and higher. Examples of carbonizable substrates are cellulose based materials like paper, brown carton, wood, etcetera. It is also conceivable that the substrate is formed by a carbonizable polymer, like polyimide. The substrate may be rigid and/or flexible.

The irradiation which is required and applied during step B) is sometimes referred to as heat. This irradiation applied during step B) is preferably generated by using a laser, in particular a gas laser, more in particular a diode laser and/or a carbon dioxide laser (CO₂ laser). Carbon dioxide lasers are the highest-power continuous wave lasers that are currently available. And they are also quite efficient: the ratio of output power to pump power can be as large as 20%. The CO₂ laser typically produces a beam of infrared light with the principal wavelength bands centering on 9.4 and 10.6 micrometres (μm). Lasers typically operate relatively fast and, moreover, are flexible, as a result of which lasers are ideally suitable to create different track, pads, or electronic circuits, or parts thereof, within a short time frame. Instead of using a laser, it is also imaginable that the substrate is irradiated position-selectively in another manner, for example by using a heated stamp to physically burn, position-selectively, the substrate. Alternatively, a mask may be applied onto the substrate after which the uncovered parts of the substrate are heated, for example by means of a heated air flow, to temperature above the carbonization temperature of about 400 degrees Celsius. Stamps and masks are typically useful in case a standard track layout and/or pad layout would be desired.

Preferably, step B) is repeated a plurality of times, such that at least one irradiated part of the substrate is irradiated a plurality of times. It has been found that repeatedly irradiating the same substrate part will improve the conductivity of this substrate part. However, it is more preferred that step B) is repeated a plurality of times, such that the at least one irradiated part of the substrate is irradiated (only) two (or three) times. By irradiating a substrate part only twice, the best conductivity results were obtained. It has been found that further irradiation of the same substrate part will affect the conductivity due to the formation of less conductive ash.

In a preferred embodiment, the method comprises step C), comprising of applying mechanical pressure onto at least one irradiated part of the substrate to compact at least one electrically conductive track and/or pad. It has been found that the electrical conductivity could further be improved by compacting the formed char (carbon particles/fibres). This leads to less porosity and an increased density which is in favour of the conductivity. Typically, without compression, and after initial carbonization, the formed carbon particles are loosely packed which may affect the conductivity of the track/pad as such. Preferably, the mechanical pressure applied exceeds to the elastic limit of the substrate. This leads to the effect that the substrate is deformed plastically (permanently), as a result of which the dense state of the formed carbon will be preserved in improved manner. To this end, the exerted mechanical pressure is at least 6 kPa, preferably at least 10 kPa, which is commonly more than the elastic limit of a typical cellulose based substrate. Here, during this plastic deformation of the substrate, the substrate thickness of the pressed parts of the substrate is reduced in a (semi-)permanent manner. Preferably, the thickness of the substrate is reduced at least partially during step C, and/or the thickness of at least one electrically conductive track and/or pad is reduced during step C).

Preferably, step C) is repeated a plurality of times, such that at least one irradiated part of the substrate is mechanically pressed a plurality of times. It has been found that repeatedly compressing the same irradiated part of the substrate will facilitate to compact the carbon particles formed. This repeating action is commonly preferred over the application of more pressure since this latter could more easily destroy the substrate in an undesired manner. It has been found that it is advantageous in case step C) is repeated a plurality of times, such that at least one irradiated part of the substrate is mechanically pressed at least five times. Here, reference is made to FIG. 2, demonstrating that a relatively good conductivity can be obtained by irradiating a substrate part twice (in which the number of overlaps equals to 2), and by applying at least 5 pressure actions to mechanically compact the generated char fraction. Typically, the track(s) and/or pad(s) are created first, after which the pressure is applied. However, it is also imaginable that the sequence of step B) and C) is executed a plurality of times. This means that step B) follows step C) at least once, which could lead to the series of steps: B), C), B), C).

The mechanical pressure is typically applied by using at least one roller. During step C), preferably, an irradiated (top) side of the substrate is firstly covered by at least one covering layer prior to applying mechanical pressure by said at least one roller. This covering layer is normally used to protect the substrate. Preferably, at least one non-stick foil, such as a metal foil, in particular an aluminium foil, is used. This prevents carbon particles to stick against the foil during the application of mechanical pressure. More preferably, the at least one non-stick foil, such as a metal foil, in particular an aluminium foil, is covered by a flexible foil, in particular a polytetrafluoroethylene (Teflon) foil prior to applying mechanical pressure by said at least one roller. This flexible (rubber-like and/or elastic) foil may equalize the pressure exerted during step C), and may in particular also secure that sufficient pressure is applied onto carbon particles/fibres which may be positioned in deepened portions of the top side of the substrate.

Instead of or in addition to applying a mechanical pressure onto at least one irradiated part of the substrate according to step C), it is also imaginable that during step C) (or another step, which may be referred to as step G)), the bond strength between the substrate and at least one marking printed and/or to be printed on said substrate. This may be achieved by applying a mechanical pressure as described above. This will lead to an improved fixation of the printed marking(s) onto the substrate. Increasing the bond strength can be realized in different manners, and can be performed prior to and/or after carbonization. Here, it is for example imaginable that the substrate is treated with a bond strength improving coating, which can, for example, by spraying, preferably by using one or more spray nozzles, onto the substrate, which may be executed prior to and/or after carbonization. The coating may be configured to react with the marking(s) to intensify the bond between the marking and at least one of the substrate and the coating. It is also imaginable that during step C) (or in another step, which may be referred to as step G)) the at least one marking is further irradiated, such that the bond strength between said at least one marking and the substrate is improved (intensified).

Preferably, the irradiated substrate is fed through a space formed in between at least one top roller, acting on an irradiated side of the substrate and/or at least one covering layer covering said irradiated (top) side of the substrate, and at least one bottom roller acting on an opposite (rear) side of the substrate. Typically, at least one of the rollers is rotated by using an electromotor. And typically, at least one of the rollers is mechanically forced towards the other roller in order to allow mechanical pressure to be exerted onto the substrate.

In a preferred embodiment of the method according to the invention, during step B) a part of the substrate is position-selectively irradiated for a period of time situated in between 0 and 5 seconds. Typically, this time interval will be sufficient to convert the substrate position-selectively into char (carbon particles/fibres).

It is commonly advantageous in case, during step B), the substrate and the at least one irradiation source, preferably a laser, and more preferably a CO2 laser, are mutually displaced by using a speed which is at least 10 mm/s. This speed is also called the printing speed, the marking speed, or the carbonization speed.

It could be advantageous in case the method comprises step E), comprising of preheating the substrate, preferably to a temperature situated in between 200 and 250 degrees Celsius, prior to performing step B). Experiments have shown that preheating the substrate prior to executing step B) could improve the char yield, and hence the conductivity. This preheating could be realized, for example, by means of an oven, an infrared heating source, and/or by the same irradiation source as used during step B). In this latter embodiment, the to be preheated part of the substrate will typically be exposed to a reduced power density to prevent premature carbonization of the substrate. This may, for example, by achieved by so-called beam-shaping, wherein the irradiating beam of the irradiation source is broadened to reduce the power density of said beam.

It is could also be advantageous in case the method comprises step F), comprising of post-irradiating at least the irradiated parts of the substrate after completion of step B), preferably by using at least one laser selected from the group consisting of: a blue laser, a green laser, a blue-green laser. These lasers generate electromagnetic radiation with a wavelength of 455-529 nm. Experiments have shown that this post-irradiation (post-illumination) further improves the blackness of the irradiated substrate parts, which is in favour of the conductivity of these substrate parts.

It is imaginable that at least one the electrically conductive track created during step B) is a linear track, preferably extending parallel to a plane defined by the substrate. However, it is also imaginable that at least one the electrically conductive track created during step B) is a non-linear track, such as a curved and/or angled track, preferably extending parallel to a plane defined by the substrate. A combination of tracks and/or pads which are mutually connected are also feasible by applying the method according to the invention.

In a preferred embodiment of the method according to the invention, the method comprises step G), comprising attaching at least one electric component to the substrate, wherein said electric component is connected to at least one electrically conductive track and/or pad created during step B). These electronic (electric) components may be attached to the substrate, for example, by using a conductive glue. In this manner, a complete electronic circuit can be realized.

It is also conceivable that during step A) a plurality of the carbonizable substrates is provided, wherein onto each substrate at least one electrically conductive track and/or pad is created, and wherein the method comprises step E) comprising of stacking of a plurality of irradiated substrates on top of each other, preferably such that at least one three-dimensional track and/or pad is formed extending through said stacked substrates. In this manner, a more complicated—3D—topography (design) of tracks and/or pads can be realized. The substrates may have the same composition, although it is also imaginable that a plurality of substrates are made of mutually distinctive compositions. Here, it could be advantageous that during step B) at least one position-selective part of the substrate is irradiated such that the at least one formed carbonized track and/or pad extends from a top side of the substrate to a rear side of the substrate. In this manner conductive pins, made of char (carbon particles/fibres) may be formed which connect to the top side and the rear side of the substrate, and which can be used to electrically connect tracks and/or pads created at or in different substrates.

It is conceivable that at least one protective coating is applied on top of the conductive tracks and/or pads formed on/in the substrate. An example of a suitable coating is polydimethylsiloxane (PDMS).

It is imaginable that the substrate is deformed, in particular folded, after formation of the at least one track and/or pad. This allows different parts of a top surface of the substrate to face each other, as a result of which the formed at least one track and/or pad can be protected (shielded) from the environment, which may be in favour of the durability and reliability of the track and/or pad formed.

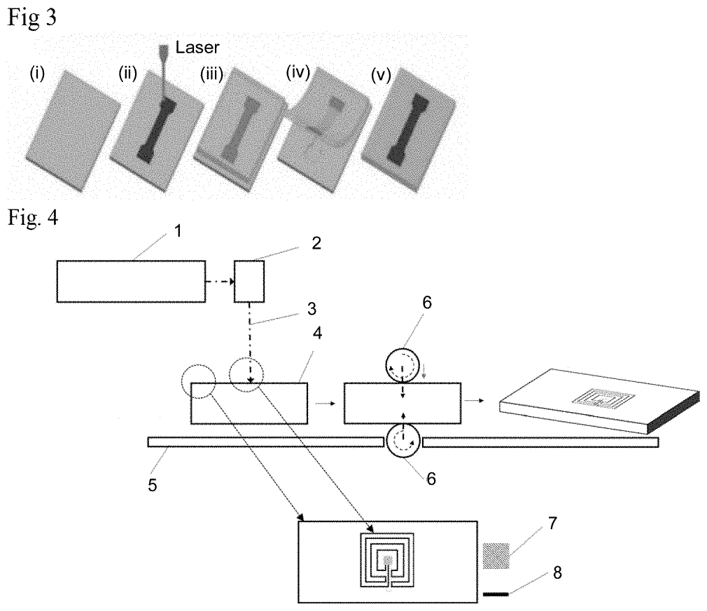

In a preferred embodiment, the at least one track and/or the at least one pad formed during step B) may be transferred to another substrate, also referred to as transfer substrate. This transfer substrate may or may not be carbonizable. An example of a (non-carbonizable) substrate is PDMS, which has (rubber-) elastic properties and is therefore, for example, more suitable (than e.g. carton) to be integrated in a wearable device. This transfer step may thus provide more freedom of design for the completion of the electronic circuit and/or the application of the track(s) and/or pad(s) created. An example of this transfer process is shown in FIG. 3, wherein FIG. 3(ii) shows the formation of an electrically conductive track onto paper or carton, wherein the track is subsequently covered by a transfer substrate, such as PDMS, (FIG. 3(iii)), after which the transfer substrate is removed from the paper of carton (FIG. 3(iv)/(v)).

The invention also relates to a device for creating at least a part of an electronic circuit, in particular by using the method according to one of the preceding claims, comprising: at least one irradiation source, in particular a laser, such as a CO₂ laser, being configured to position-selectively irradiate at least one part of a carbonizable substrate to a temperature exceeding the carbonization temperature of said substrate, such that the irradiated part of the substrate is carbonized to form at least one electrically conductive track and/or pad. Further hardware components that may be used in the device according to the invention, such as pressurizing means for applying a mechanical pressure, a preheating source, a post-irradiation laser, as referred to above, may make part of the device according to the invention. The device is typically controlled by using a control unit, which is connected to the different hardware components used. Preferably, the device comprises one or more temperature sensors, and/or one or more optical sensors, and/or one or more chemical sensors, to control (and verify) the carbonization process as such.

The invention moreover relates to an electronic circuit, or at least a part thereof, created by applying the method according to the invention. The electronic circuit may be formed by a microsystem. The electronic circuit may be part of a wearable device to be worn by persons and/or animals. The wearable device, in particular the electronic circuit thereof, may be configured as wearable sensor, in particular in order to help monitor health and/or provide clinically relevant data for care.

A non-limitative example of a device according to the invention is shown in FIG. 4. More in particular, this figure discloses that the device comprises a laser (1), in particular a CO₂ laser, and a laser positioning system (2), preferably a galvanometric system (2) for guiding and shaping an electromagnetic beam (3) generated by the laser (1) towards a carbonizable substrate (4) to position-selectively heat the substrate (4) to a temperature above 400 degrees Celsius to chemically convert the substrate, position-selectively, into conductive char (carbon particles and/or carbon fibres). In this manner electrically conductive tracks and/or pads are formed. The utilised laser beam (3) characteristics are such that it has sufficient absorption by the substrate such that the substrate can reach the required temperatures of the carbonisation reaction. Once at least one electrically conductive track and/or pad are (inklessly) printed on the substrate, or even during the printing process, the substrate (4) is conveyed by means of a conveyor (5) to pressurizing means (6) for applying a mechanical pressure, which leads to a more dense char fraction, which increases the conductivity of this fraction. The pressurizing means (6) comprise, in this embodiment, a set of rollers (6) which apply mechanical pressure over the prints with the intent to compact them without (seriously) destroying the substrate. However, some plastic deformation may occur here. In this particular example, the generated electrically conductive print is a RFID tag antenna which is shown as black traces (8) which is connected to a tiny microcontroller (7). The antenna traces (8) are printed by the device, while the microcontroller (7) comes preassembled and is placed on top of the substrate, making electrical connection to the conductive tracks (8) printed by the inkless printer thereby making an RFID tag. The microcontroller may, for example, be glued onto the substrate (4) by using a conductive glue.

It will be apparent that the invention is not limited to the working examples shown and described herein, but that numerous variants are possible within the scope of the attached claims that will be obvious to a person skilled in the art.

The verb “comprise” and conjugations thereof used in this patent publication are understood to mean not only “comprise”, but are also understood to mean the phrases “contain”, “substantially consist of”, “formed by” and conjugations thereof. Where the term “print” is used, a position-selective carbonized marking is meant. With “position-selective” typically a specific, predefined part of the substrate is meant, although it is also conceivable that this part could extend to a complete (top) side of the carbonizable substrate. Where the term “irradiation” is used, this may be interpreted as “direct irradiation”, wherein an, optionally, shaped, irradiated beam directly (without intervention of an intermediate layer or intermediate component) hits the substrate, and may also be interpreted as “indirect irradiation”, wherein an, optionally, shaped, irradiated beam indirectly, via at least one intermediate layer or intermediate component, hits the substrate. An example of an intermediate layer could be, for example, a transparent plate and/or another substrate.

1. A method of creating at least a part of an electronic circuit, comprising:
A) providing at least one carbonizable substrate, in particular a cellulose based substrate,
B) position-selectively irradiating at least one part of the substrate to a temperature exceeding the carbonization temperature of said substrate, such that the irradiated part of the substrate is carbonized to form at least one electrically conductive track and/or pad.

2. The method according to claim 1, wherein B) is repeated a plurality of times, such that at least one irradiated part of the substrate is irradiated a plurality of times.

3. The method according to claim 1, wherein B) is repeated a plurality of times, such that the at least one irradiated part of the substrate is irradiated two or three times.

4. The method according to claim 1, further comprising:
C) applying mechanical pressure onto at least one irradiated part of the substrate to compact at least one electrically conductive track and/or pad.

5. The method according to claim 4, wherein the mechanical pressure applied exceeds to the elastic limit of the substrate.

6. The method according to claim 4, wherein C) is repeated a plurality of times, such that at least one irradiated part of the substrate is mechanically pressed a plurality of times.

7. The method according to claim 4, wherein C) is repeated a plurality of times, such that at least one irradiated part of the substrate is mechanically pressed at least five times.

8. The method according to claim 2, further comprising:
C) applying mechanical pressure onto at least one irradiated part of the substrate to compact at least one electrically conductive track and/or pad, wherein a sequence of B) and C) is executed a plurality of times.

9. The method according to claim 4, wherein the exerted mechanical pressure is at least 6 kPa.

10. The method according to claim 4, wherein during C) the substrate thickness is reduced at least partially and/or wherein during C) the thickness at least one electrically conductive track and/or pad is reduced.

11. The method according to claim 4, wherein the mechanical pressure is applied by using at least one roller.

12. The method according to claim 11, wherein during C) an irradiated side of the substrate is firstly covered by at least one covering layer prior to applying mechanical pressure by said at least one roller.

13. The method according to claim 12, wherein during C) an irradiated side of the substrate is firstly covered by at least one non-stick foil, such as a metal foil, in particular an aluminium foil.

14. The method according to claim 13, wherein the at least one non-stick foil, such as a metal foil, in particular an aluminium foil, is covered by a flexible foil, in particular a polytetrafluoroethylene (Teflon) foil prior to applying mechanical pressure by said at least one roller.

15. The method according to claim 11, wherein the irradiated substrate is fed through a space formed in between at least one top roller, acting on an irradiated side of the substrate and/or at least one covering layer covering said irradiated side of the substrate, and at least one bottom roller acting on an opposite side of the substrate.

16. The method according to claim 1, wherein during B) a part of the substrate is position-selectively irradiated for a period of time situated in between 0 and 5 seconds.

17. The method according to claim 1, wherein during B) a part of the substrate is position-selectively irradiated by using at least one irradiation source.

18. The method according to claim 17, wherein during B) the substrate and the at least one irradiation source are mutually displaced by using a speed which is at least 10 mm/s.

19. The method according to claim 1, wherein the method further comprises:
E) preheating the substrate prior to performing B).

20. The method according to claim 1, wherein the method further comprises:
F) post-irradiating at least the irradiated parts of the substrate after completion of B).

21. The method according to claim 1, wherein during B) the temperature of the at least one irradiated part of substrate is brought to at least 400 degrees Celsius.

22. The method according to claim 1, wherein the substrate is formed by paper and/or carton.

23. The method according to claim 1, wherein at least one electrically conductive track created during B) is a linear track.

24. The method according to claim 1, wherein at least one electrically conductive track created during B) is a non-linear track.

25. The method according to claim 1, wherein during B) a plurality of electrically conductive tracks and/or pads are created which are mutually connected.

26. The method according to claim 1, wherein the method further comprises:
D) attaching at least one electric component to the substrate,
wherein said electric component is connected to at least one electrically conductive track and/or pad created during step B).

27. The method according to claim 1, wherein during A) a plurality of the carbonizable substrates is provided, wherein onto each substrate at least one electrically conductive track and/or pad is created, and wherein the method further comprises:
E) stacking of a plurality of irradiated substrates on top of each other.

28. The method according to claim 1, wherein during B) at least one position-selective part of the substrate is irradiated such that the at least one formed carbonized track and/or pad extends from a top side of the substrate to a rear side of the substrate.

29. The method according to claim 1, wherein the method further comprises:
G) increasing the bond strength between at least one electrically conductive track and/or pad printed and/or to be printed during B) and the substrate.

30. A device for creating at least a part of an electronic circuit, by using the method according to one of the preceding claims, comprising: at least one irradiation source, in particular a laser, such as a CO₂ laser, being configured to position-selectively irradiate at least one part of a carbonizable substrate to a temperature exceeding the carbonization temperature of said substrate, such that the irradiated part of the substrate is carbonized to form at least one electrically conductive track and/or pad.

31. An electronic circuit, or at least a part thereof, created by applying the method according to claim 1.

32. The method according to claim 19, wherein the substrate is preheated to a temperature in the range of 200 to 250 degrees Celsius.

33. The method according to claim 20, wherein the post-irradiating is conducted by at least one laser selected from the group consisting of: a blue laser, a green laser, and a blue-green laser

34. The method according to claim 27, wherein at least one three-dimensional track and/or pad is formed extending through the plurality of irradiated substrates stacked on top of each other.

35. The method according to claim 17, wherein the at least one irradiation source is a CO₂ laser.

36. The method according to claim 23, wherein the linear track extends parallel to a plane defined by the substrate.

37. The method according to claim 24, wherein the non-linear track extends parallel to a plane defined by the substrate.
